(19) United States
(12) Patent Application Publication
(10) Pub. No.: US 2012/0126313 A1
(43) Pub. Date: May 24, 2012

(54) ULTRA THIN DIE TO IMPROVE SERIES RESISTANCE OF A FET

(75) Inventors: Rohan S. Braithwaite, Gilbert, AZ (US); Randy L. Yach, Phoenix, AZ (US); Daniel J. Jackson, Phoenix, AZ (US); Gregory Dix, Tempe, AZ (US)

(73) Assignee: Microchip Technology Incorporated

(21) Appl. No.: 13/288,219

(22) Filed: Nov. 3, 2011

Related U.S. Application Data
(60) Provisional application No. 61/416,420, filed on Nov. 23, 2010.

(51) Int. Cl. H01L 29/78; H01L 21/336

(52) U.S. Cl. 257/329; 438/268; 257/E29.262; 257/E21.41

(57) ABSTRACT

A method for producing a power field effect transistor (FET) device having a low series resistance between the drain and source when switched on has the steps of: forming a vertical power FET in a semiconductor die; and back-grinding the semiconductor die to a thickness of less than or equal to about 100 μm (4 mils) or less.

### CROSS-REFERENCE TO RELATED APPLICATIONS

This application claims the benefit of U.S. Provisional Application No. 61/416,420 filed on Nov. 23, 2010, entitled “ULTRA THIN DIE TO IMPROVE SERIES RESISTANCE OF A FET”, which is incorporated herein in its entirety.

### TECHNICAL FIELD

The present disclosure relates to fabrication of field effect transistors (FETs), and more particularly, to back-grinding a semiconductor die to enable obtaining a low RDS(ON) for a field effect transistor (FET) fabricated therein.

### BACKGROUND

Present technology power FETs are fabricated on a semiconductor die having a thickness equal to or greater than 127 μm (5 mils). Most semiconductor dies have a thickness of about 178 μm (7 mils). In particular when vertical power transistors are implemented in such dies, these semiconductor die thicknesses can result in a higher resistance for the RDS(ON) of a power FET. One way to reduce RDS(ON) resistance is to heavily dope the substrate. However, this option may not be always available.

### SUMMARY

According to an embodiment, a method for producing a power field effect transistor (FET) device having a low series resistance between the drain and source when switched on, may comprise the steps of: forming a vertical power FET in a semiconductor die; and back-grinding the semiconductor die to a thickness of less than or equal to about 100 μm (4 mils) or less.

According to a further embodiment, the thickness can be from about 100 μm (4 mils) to about 25 μm (1 mils). According to a further embodiment, the step of forming a vertical power FET may comprise: forming a cell structure comprising first and second source regions of a first conductivity type for a vertical DMOS-FET in an epitaxial layer of a second conductivity type arranged on a substrate of a first conductivity type, wherein the first and second source regions are spaced apart by a predefined distance; forming an insulated gate layer on top of said epitaxial layer; patterning the gate layer to form first and second gates being spaced apart from each other. According to a further embodiment, the step of patterning may be performed in a single step. According to a further embodiment, the step of patterning the gate layer may provide for a bridging area of the gate layer connecting the first and second gates. According to a further embodiment, the bridging area can be located outside the cell structure. According to a further embodiment, the method may further comprise connecting the first and second gates by a metal layer. According to a further embodiment, the method may further comprise: mounting the semiconductor die on a leadframe; connecting a top area of said semiconductor die with external contacts. According to a further embodiment, the a top area can be connected by a plurality of bond wires. According to a further embodiment, the plurality of bond wires each may comprise a thickness of about 0.254 mm (10 mils). According to a further embodiment, the top area can be connected by a metal clip. According to a further embodiment, the metal clip can be manufactured from copper. According to a further embodiment, the metal clip may provide for a section compensating for a semiconductor die thickness.

According to another embodiment, a power field effect transistor (FET) device having a low series resistance between the drain and source when switched on, may comprise a semiconductor die comprising a vertical power FET; wherein the semiconductor die is back-ground to a thickness of less than or equal to about 100 μm (4 mils) or less.

According to a further embodiment of the power FET, the thickness can be from about 100 μm (4 mils) to about 25 μm (1 mil). According to a further embodiment of the power FET, the vertical FET can be a vertical diffused metal oxide semiconductor (DMOS) field-effect transistors (FET), with a cell structure comprising: a substrate of a first conductivity type forming a drain region; an epitaxial layer of the first conductivity type on said substrate; first and second base regions of the second conductivity type arranged within said epitaxial layer and spaced apart by a predefined distance; first and second source regions of a first conductivity type arranged within said first and second base region, respectively; a gate structure insulated from said epitaxial layer by an insulation layer and arranged above the region between the first and second base regions and covering at least partly said first and second base region, wherein the gate structure comprises first and second gates being spaced apart wherein each gate covers a respective portion of said base region.

According to a further embodiment of the power FET, the vertical FET may further comprise a source metal layer connecting said first and second source region and said first and second base region. According to a further embodiment of the power FET, the vertical FET may further comprise a gate metal layer connecting said first and second gate. According to a further embodiment of the power FET, the first and second gate can be formed by a gate layer that connects the first and second gate. According to a further embodiment of the power FET, the first and second gate can be connected outside the cell structure. According to a further embodiment of the power FET, the vertical FET may further comprise a leadframe on which the semiconductor die is mounted, wherein a top area of said semiconductor die is connected with external contacts. According to a further embodiment of the power FET, a top area can be connected by a plurality of bond wires. According to a further embodiment of the power FET, the plurality of bond wires each may comprise a thickness of about 0.254 mm (10 mils). According to a further embodiment of the power FET, a top area can be connected by a metal clip. According to a further embodiment of the power FET, the metal clip can be manufactured from copper. According to a further embodiment of the power FET, the metal clip may provide for a section compensating for a semiconductor die thickness.

According to yet another embodiment, an integrated circuit device may comprise at least one vertical FET as described above, wherein the integrated circuit device provides for control functions for a switched mode power supply.

According to a further embodiment of the integrated circuit device, the integrated circuit device may comprise a microcontroller controlling said at least one vertical FET.

### BRIEF DESCRIPTION OF THE DRAWINGS

FIG. 1 shows a first embodiment of an improved vertical DMOS-FET.

FIG. 2 shows a first embodiment of an improved vertical DMOS-FET.

FIG. 3A-3F show several exemplary process steps for manufacturing a device as shown in FIG. 2.

FIG. 4 shows an arrangement of an semiconductor die with a power MOSFET according to various embodiments in a flip chip configuration; and

FIG. 5 shows another embodiment of a flip-chip power MOSFET;

FIG. 6 shows applications of the improved vertical DMOS-FET in single integrated chip.

FIG. 7A-7B show an embodiment of a power MOSFET according to various embodiments using wire bonding.

FIG. 8 shows yet another embodiment using multiple bond wires for connecting the transistor to external contacts

### DETAILED DESCRIPTION

Power metal oxide semiconductor field-effect transistors (MOSFET) are generally used to handle high power levels in comparison to lateral transistors in integrated circuits. According to various embodiments, it is desirable to lower the RDS(ON) of such a vertical power FET so as to improve efficiency of a product, e.g., a discrete or integrated power MOSFET, a power MOSFET in an integrated switch mode power supply (SMPS), a power MOSFET in combination and/or integrated with a microcontroller, etc. when using the power FET as a power switch. According to the teachings of this disclosure, a semiconductor die is back-grinded to a thickness of less than about 100 μm (4 mils), e.g., from about 25 (1 mils) to about 100 μm (4 mils), which will improve (reduce) the series resistance between the drain and source RDS(ON) of a power FET, in particular a vertical power FET, when on, and thereby increasing the efficiency of the power FET when used as a switch, e.g., for the power switch of a SMPS.

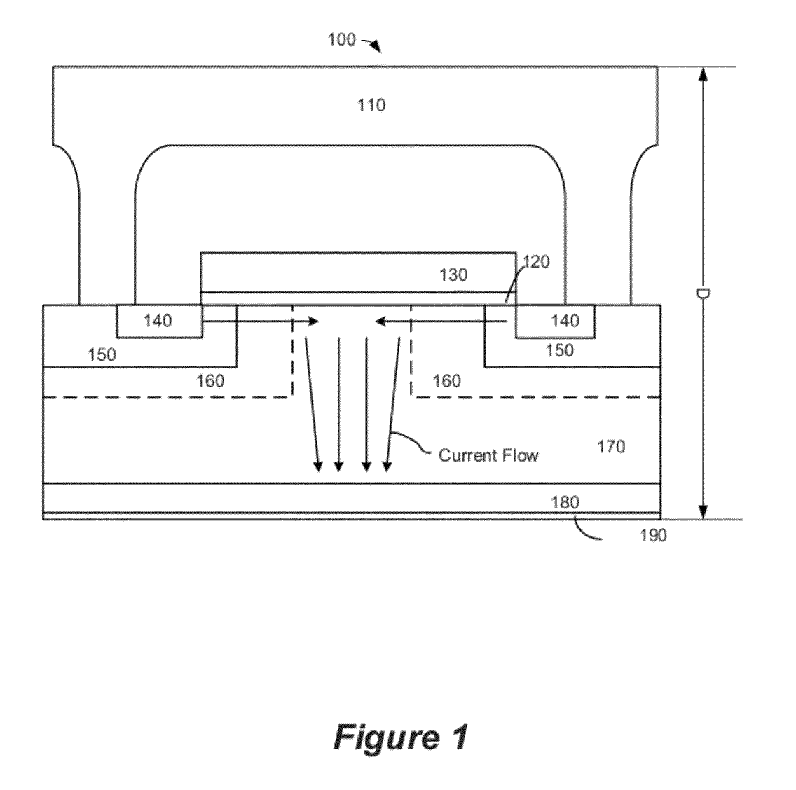

Referring to FIG. 1, depicted is a schematic elevational view of an ultra-thin die having a vertical power FET fabricated therein, according to a specific example embodiment of this disclosure. FIG. 1 shows a typical MOSFET which uses a vertical diffused MOSFET structure, also called double-diffused MOSFET structure (DMOS or VDMOS).

As shown for example, in FIG. 1, on an N⁺ substrate 180 there is a N⁻ epitaxial layer 170 formed whose thickness and doping generally determines the voltage rating of the device. From the top into the epitaxial layer 170 there are formed N⁺ doped left and right source regions 140 surrounded by P-doped region 150 which form the P-base which can be surrounded by respective out diffusion areas 160. A source contact metal layer 110 may generally contact both regions 140 and 150 on the surface of the die and also connects both left and right source regions. An insulating layer 120, typically silicon dioxide or any other suitable material, insulates a polysilicon gate 130 which covers a part of the P-base region 150 and out diffusion area 160. The gate 130 is connected to a gate contact (not shown) which is usually formed by another metal layer. The bottom side of this vertical transistor has thin metal layer 190 applied after the die has been back grinded to its final thickness D. This metal layer forms the drain contact. FIG. 1 shows a typical elementary cell of a MOSFET that can be very small and comprises a common drain, a common gate and two source regions and two channels. Other similar cells may be used in a vertical power MOS-FET. A plurality of such cells may generally be connected in parallel to form a power MOSFET in a single die. As shown on the right side of FIG. 1 once the transistor structure has been completed according to various process steps as will be explained in more detail below, the backside, i.e. the substrate of the die is grinded down. Thus, the resistance of the source-drain load path of the transistor can be significantly reduced as the substrate contributes a major factor for the overall on-resistance of such a vertical MOSFET.

In the On-state, a channel is formed within the area of region 150 covered by the gate 130 reaching from the surface into the regions 160, respectively. Thus, current can flow as indicated by the horizontal arrows. The cell structure must provide for a sufficient width of gate 130 to allow for this current to turn into a vertical current flowing to the drain side as indicated by the vertical arrows.

As stated above the major influence for the on-resistance is contributed by the substrate 180. By grinding the thickness of this layer down, the resistance can be substantially reduced.

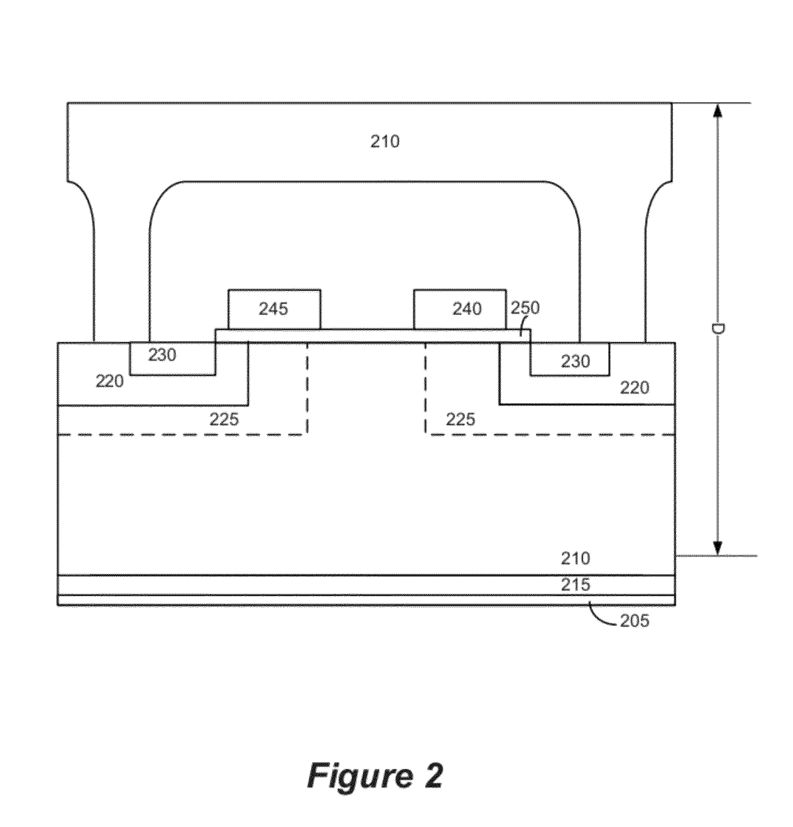

FIG. 2 shows a cross-sectional view of another vertical DMOS-FET according to other embodiments. Again, an N⁺ substrate 215 is provided on top of which an N⁻ epitaxial layer 210 is formed. From the top into the epitaxial layer 210 there are formed N⁺ doped left and right source regions 230 each surrounded by a P-doped region 220 which forms the P-base. Each P-base 220 is surrounded by an associated out diffusion area 225. Similar as for the transistor shown in FIG. 1, a source contact 260 generally contacts both regions 230 and 220 on the surface of the die and is generally formed by a metal layer that connects both left and right source region. Contrary to the vertical DMOS-FET shown in FIG. 1, an insulating layer 250 insulates separate left and right gates 240 and 245 each covering a part of the respective left and right P-base region 220 and associated out diffusion area 225. The gates can be interconnected, for example by means of a metal or contact layer (not shown) or connect to common gate area outside the gate effective area as will be explained in more detail below. Thus, according to various embodiments, the cell proposed structure does not only create two source regions 220, 225, 230 and two channels but also two polysilicon gates 240 and 245. The bottom side of this vertical transistor has again another metal layer 205 forming the drain contact after the die has been back grinded to its final thickness D.

As mentioned above, according to various embodiments, the gates 240 and 245 do substantially not overlap such that two distinct gates are formed. Thus, the combined gate area for gates 240 and 245 when seen from atop is smaller than that of a conventional vertical transistor. Hence, the resulting individual gate-source and gate-drain capacitances are effectively are in sum smaller than the respective gate capacitances of a vertical DMOS-FET as for example shown in FIG. 1. The various embodiments thus effectively take out the middle portion of the gate 130 of the DMOS-FET shown in FIG. 1 thereby splitting the gate into two distinct gates 240 and 245. This can be done as much of the polysilicon is unnecessary for channel control. Thus, by removing the middle portion, the effective gate capacitance of this cell can be lowered without affecting the performance of the device. Depending on the manufacturing process, the split gate can be created by patterning of the polysilicon layer in a single step. Hence, no additional masking steps are required. The middle section of gate 130 that is to be taken out may be very small, however, available lithography techniques will be capable of resolving the spaces involved and thus allow to create such a structure.

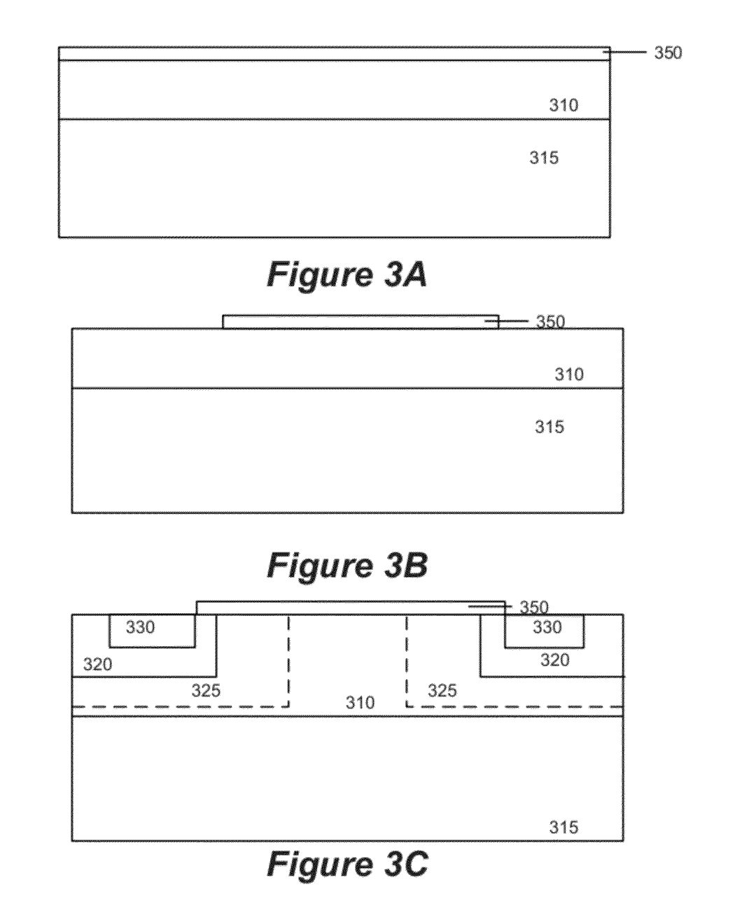

FIG. 3A-3F show exemplary process steps for manufacturing a device as shown in FIG. 2. According to the applied technology other steps or structures may be suitable to produce similar devices. As shown in FIG. 3A, an N⁻ doped epitaxial layer 310 is grown on an N⁺ substrate 315. On top of the epitaxial layer 310 an oxide layer 350 is deposited. The oxide layer 350 can be patterned as shown in FIG. 3B and N⁺-doped source regions 330 and surrounding base regions 320 with associated out diffusion areas 325 can be created with well known diffusion techniques as shown in FIG. 3C. FIG. 3D shows the die with a polysilicon layer 305 which is deposited on top of the die. This polysilicon layer 305 can then be patterned using known masking techniques to form gates 340 and 345 as shown in FIG. 3E. FIG. 3F shows the cell structure with an additional metal layer 390 connecting the left and right source regions 330 and associated P-base regions 320. As indicated by reference symbol D', the die at this stage may have a thickness of D'. According to various embodiments, the backside, i.e. the substrate 315 is now grinded down to a predefined thickness such that the overall thickness D of the die is reduced to a thickness D from about 25 (1 mils) to about 100 μm (4 mils). Once this overall thickness has been achieved, the back metal layer contacting the drain region 315 can be applied.

The step of patterning the gate layer 305 can be performed in one single step. Thus, no additional process step is required. However, according to other embodiments, more than one step may be used. For example, if the gate as shown in FIG. 1 is used as a mask to form the source regions then splitting the gates into two separate gates may be performed by another step.

The principles according to the various manufacturing steps discussed above, in particular the step or steps shown in FIG. 3F also apply to a MOSFET as shown in FIG. 1 or any other type of vertical power FET. Thus, reducing the semiconductor die thickness may apply to many different types of vertical semiconductors and is not limited to the one shown in FIGS. 3A-F.

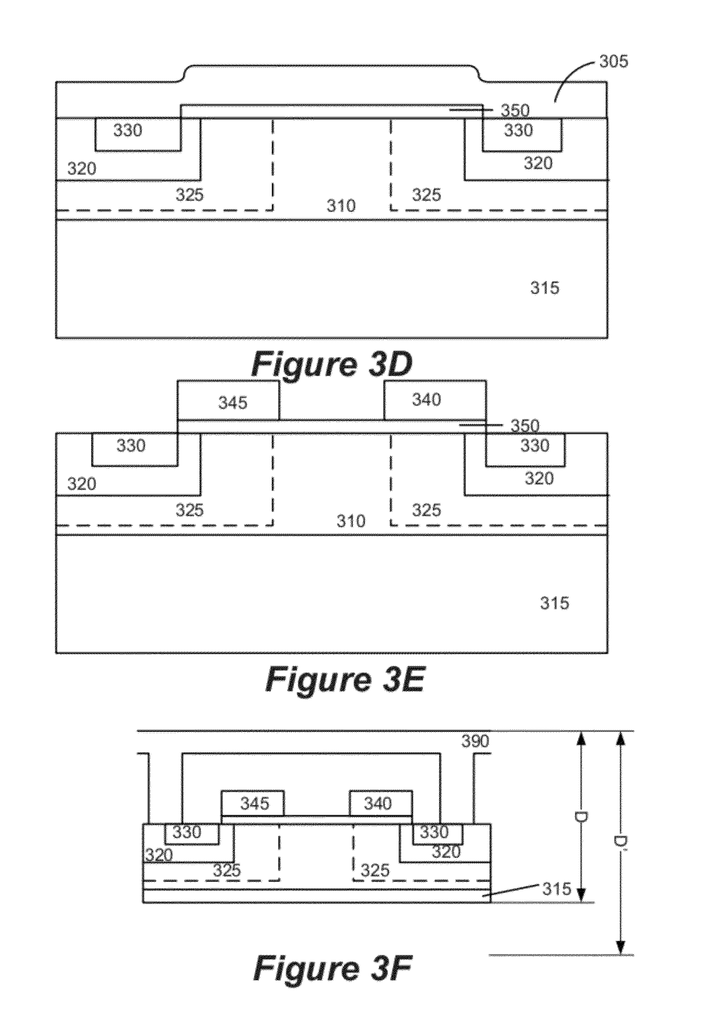

FIG. 4 shows a top view of a cell 300 according to FIG. 2 wherein only certain areas of the cell are highlighted. As can be seen, the left and right source regions 330 are surrounded by the P-base region 320. The broken lines indicates the position of the overlaid gates 340 and 345. Mid section 400 of the gate layer is removed to form individual left gate 345 and right gate 340. The gate layer 400 may be patterned to completely separate left and right gate by removing the inner section 420 and a metal layer may be used to connect the individual gate portions on the chip. According to other embodiments, well known bonding techniques may be used to connect the gates, for example outside the chip by means of a leadframe as will be explained in more detail below. However, the gate layer 305 can also be patterned as shown in FIG. 4 such that a bridging area 410 is formed outside the cell area. However, according to other embodiments, the bridging area 410 may reach into the cell and cover an insubstantial part of the cell without influencing the gate capacitance significantly. The polysilicon layer 305 may be furthermore patterned to connect a plurality of gates from neighboring cells as indicated by the dotted lines on the left and right and bottom sides of the gate structure shown in FIG. 4.

The cell structure can be a stripe structure as shown in FIG. 4. However, according to other embodiments may use square cells, hexagonal shapes or any other suitable cell shape for which the principle of the various embodiments can be applied to. The cell structure or a plurality of cells can be used to form a power DMOS-FET within an integrated circuit or in a discrete transistor device. Such an integrated circuit may provide control circuits for use in a switched mode power supply. Thus, no external power transistors may be necessary.

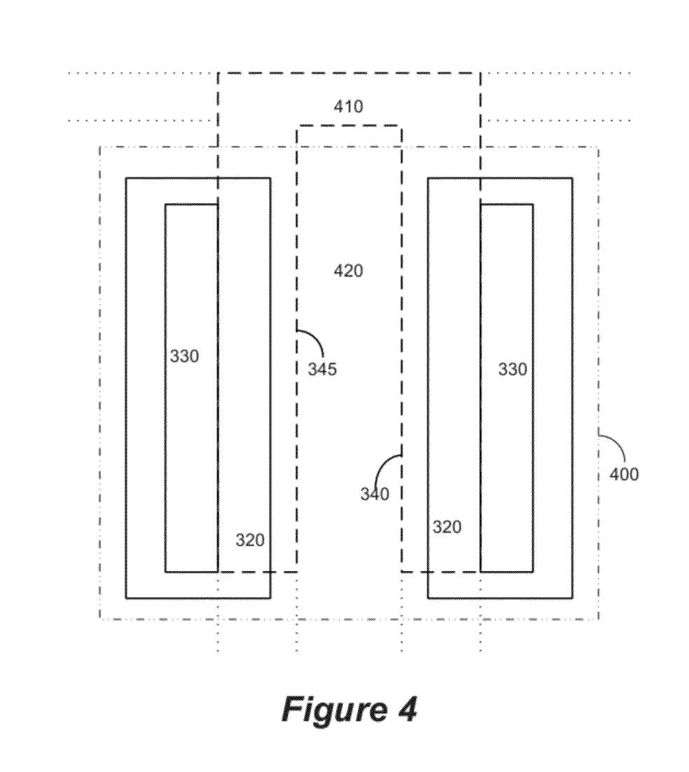

FIG. 5 shows a first application of mounting a power MOSFET die 520 on a leadframe 510a, b. Here the MOSFET transistor die is mounted to a leadframe using conventional technology. The backside of the die 520 which comprises the drain connection is directly connected with the leadframe section 510a. Instead of conventional bond wires, a clip 530 is used to connect a specific area on the top surface of the semiconductor die with one or more lead fingers of the leadframe. Here, for example, a source contact area on the surface of semiconductor die 520 is connected with a respective leadframe part 510b. The clip 530 can be manufactured from copper to provide for a low resistance. According to an embodiment, clip 530 may comprise an angled section to compensate for the thickness of the MOSFET transistor die 520. The arrangement shown in FIG. 5 can be packaged in any type of conventional housing using known techniques.

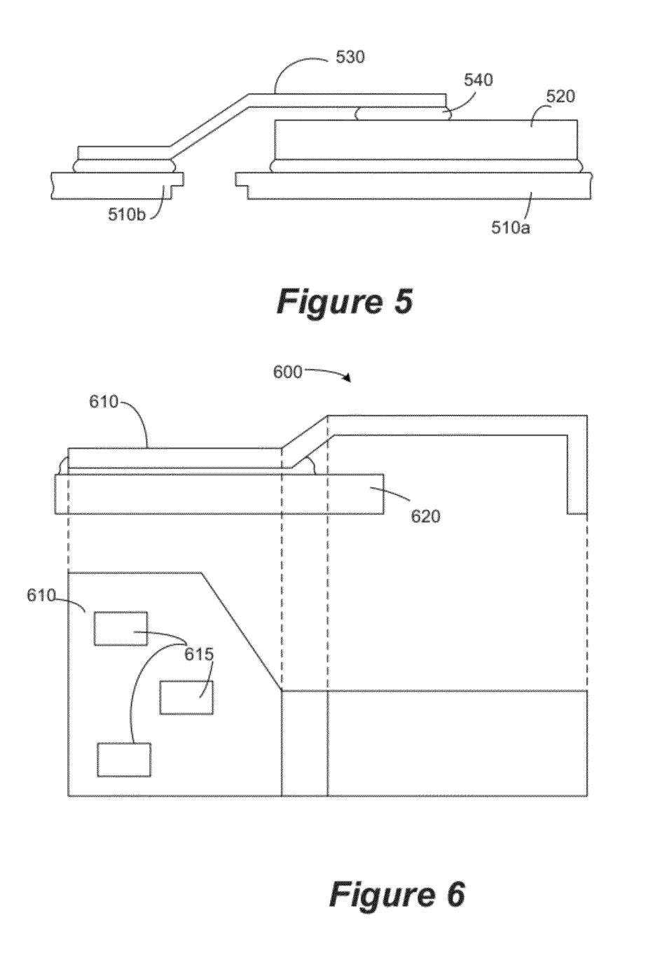

FIG. 6 shows another example of a MOSFET transistor assembly 600. Here a clip 610 is mounted directly to the drain of transistor die 620. Thus, clip 610 can form a support structure for MOSFET die 620. Clip 610 may comprise a plurality of window openings 615. The multiple window openings 615 in the clip 610 allow the solder to flow up out of the holes/windows which can improve the bonding between these elements and, thus, will help hold the clip on the die.

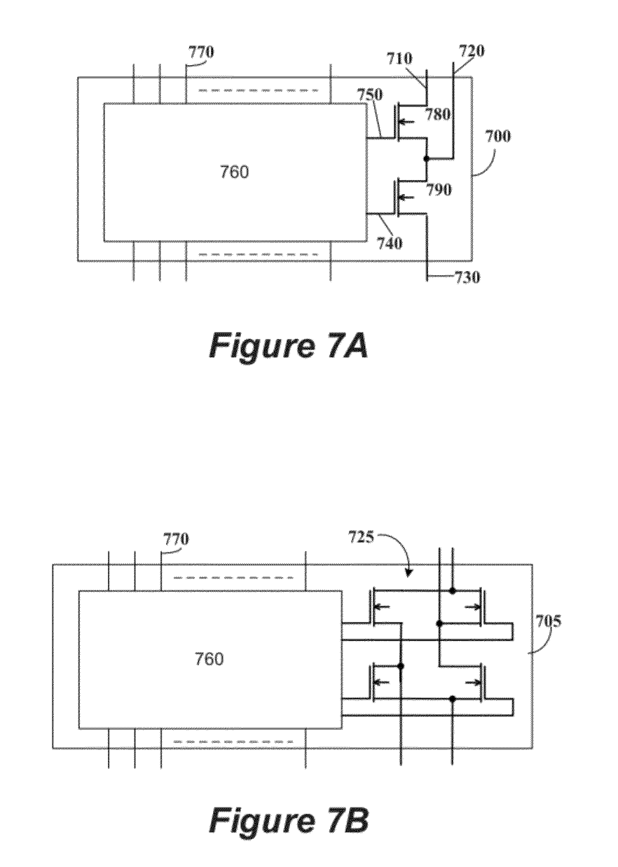

FIG. 7A shows schematically how a microcontroller 760 can be combined with two power transistors 780 and 790 according to various embodiments as shown in FIGS. 1-6 on a single chip 700. Alternatively, the microcontroller 760 and the transistors 780, 790 each may be provided on separate chips within a single housing. According to yet another embodiment, transistors 780 and 790 can be combined on a single chip and microcontroller 760 can be formed on a single chip. Other combinations are possible. Moreover, the above mentioned clip technology can be used for providing low resistance connections with external pins, for example, for source and/or drain of the MOSFET.

Microcontroller 760 may have a plurality of peripheral devices such as controllable drivers, modulators, in particular pulse width modulators, timers etc. and is capable to drive the gates 740 and 750 of transistors 780 and 790 directly or through respective additional drivers. The chip 700 can be configured to make a plurality of functions of the microcontroller available through external connections or pins 770. The source of first transistor 780 can be connected to external connection or pin 710. Similarly, external connection 720 provides a connection to the combined drain and source of transistors 780 and 790 and external connection or pin 730 for the drain of the second transistor 730. Other transistor structures manufactured in accordance with the various embodiments disclosed can be used, such as an H-bridge or multiple single transistors. FIG. 7B shows an exemplary plurality of MOSFETs connected to form an H-Bridge 725 that can be coupled with a microcontroller 760 or modulator within a single semiconductor chip 705.

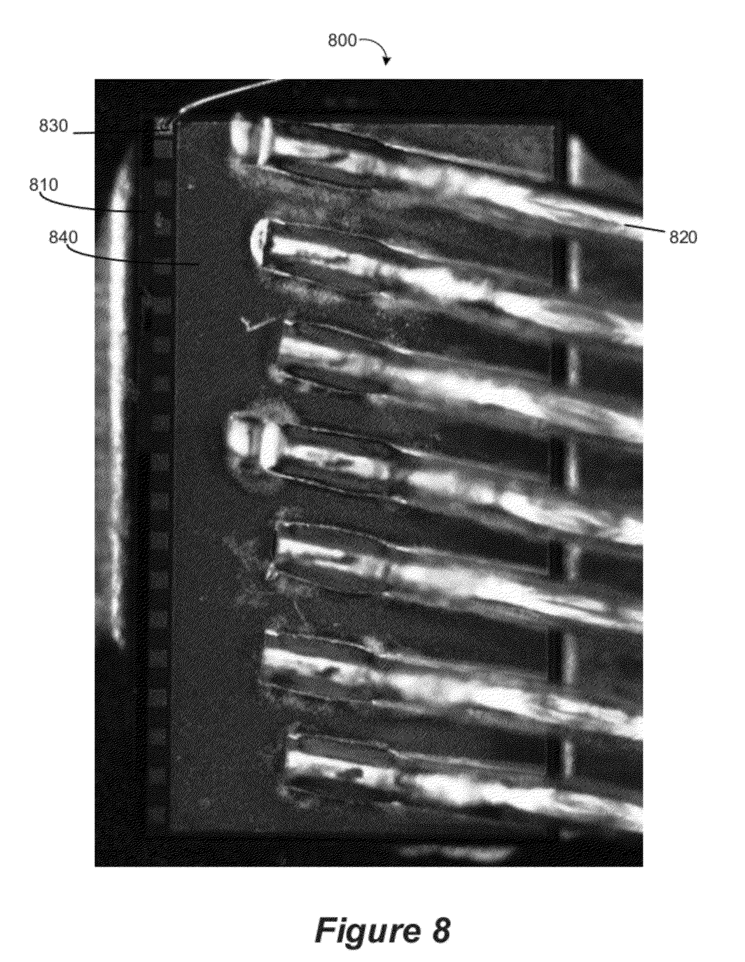

FIG. 8 shows yet another embodiment using multiple bond wires for connecting the transistor to external contacts. Here semiconductor chip 810 is mounted on a lead frame or other support structure. A Source contact area 840 is connected with respective external contacts of a housing, for example, respective leadframe fingers, by means of a plurality of low resistance bond wires 820. FIG. 8 also shows other smaller bond pads 830, for example, connections of a microcontroller or gate bond pads which are connected by conventional bond wires. The bond pads can be standard Al/Si/Cu bond pads according to one embodiment. However, the bond pads could also be Copper as well. This may depend on the metallization scheme which is being employed.

Furthermore, the exemplary embodiment shows a N-channel device with appropriate conductivity types of the different regions. A person skilled in the art will appreciate that the embodiments of the present application are not restricted to N-channel devices but can be also applied to P-Channel devices.

While embodiments of this disclosure have been depicted, described, and are defined by reference to example embodiments of the disclosure, such references do not imply a limitation on the disclosure, and no such limitation is to be inferred. The subject matter disclosed is capable of considerable modification, alteration, and equivalents in form and function, as will occur to those ordinarily skilled in the pertinent art and having the benefit of this disclosure. The depicted and described embodiments of this disclosure are examples only, and are not exhaustive of the scope of the disclosure.

What is claimed is:

1. A method for producing a power field effect transistor (FET) device having a low series resistance between the drain and source when switched on, said method comprising the steps of:
forming a vertical power FET in a semiconductor die; and
back-grinding the semiconductor die to a thickness of less than or equal to about 100 μm (4 mils) or less.

2. The method according to claim 1, wherein the thickness is from about 100 μm (4 mils) to about 25 μm (1 mils).

3. The method according to claim 1, wherein the step of forming a vertical power FET comprises:
forming a cell structure comprising first and second source regions of a first conductivity type for a vertical DMOS-FET in an epitaxial layer of a second conductivity type arranged on a substrate of a first conductivity type, wherein the first and second source regions are spaced apart by a predefined distance;
forming an insulated gate layer on top of said epitaxial layer;
patterning the gate layer to form first and second gates being spaced apart from each other.

4. The method according to claim 3, wherein the step of patterning is performed in a single step.

5. The method according to claim 3, wherein the step of patterning the gate layer provides for a bridging area of the gate layer connecting the first and second gates.

6. The method according to claim 5, wherein the bridging area is located outside the cell structure.

7. The method according to claim 3, further comprising connecting the first and second gates by a metal layer.

8. The method according to claim 1, further comprising:
mounting the semiconductor die on a leadframe;
connecting a top area of said semiconductor die with external contacts.

9. The method according to claim 8, wherein a top area is connected by a plurality of bond wires.

10. The method according to claim 9, wherein the plurality of bond wires each comprise a thickness of about 0.254 mm (10 mils).

11. The method according to claim 8, wherein a top area is connected by a metal clip.

12. The method according to claim 11, wherein the metal clip is manufactured from copper.

13. The method according to claim 10, wherein the metal clip provides for a section compensating for a semiconductor die thickness.

14. A power field effect transistor (FET) device having a low series resistance between the drain and source when switched on, comprising:
a semiconductor die comprising a vertical power FET; wherein
the semiconductor die is back-ground to a thickness of less than or equal to about 100 μm (4 mils) or less.

15. The power FET according to claim 14, wherein the thickness is from about 100 μm (4 mils) to about 25 μm (1 mils).

16. The power FET according to claim 14, wherein the vertical FET is a vertical diffused metal oxide semiconductor (DMOS) field-effect transistors (FET), with a cell structure comprising:
a substrate of a first conductivity type forming a drain region;
an epitaxial layer of the first conductivity type on said substrate;
first and second base regions of the second conductivity type arranged within said epitaxial layer and spaced apart by a predefined distance;
first and second source regions of a first conductivity type arranged within said first and second base region, respectively;
a gate structure insulated from said epitaxial layer by an insulation layer and arranged above the region between the first and second base regions and covering at least partly said first and second base region, wherein the gate structure comprises first and second gates being spaced apart wherein each gate covers a respective portion of said base region.

17. The vertical FET according to claim 16, further comprising a source metal layer connecting said first and second source region and said first and second base region.

18. The vertical FET according to claim 16, further comprising a gate metal layer connecting said first and second gate.

19. The vertical FET according to claim 16, wherein the first and second gate are formed by a gate layer that connects the first and second gate.

20. The vertical FET according to claim 19, wherein the first and second gate are connected outside the cell structure.

21. The vertical FET according to claim 14, further comprising,
a leadframe on which the semiconductor die is mounted, wherein
a top area of said semiconductor die is connected with external contacts.

22. The vertical FET according to claim 21, wherein the a top area is connected by a plurality of bond wires.

23. The vertical FET according to claim 22, wherein the plurality of bond wires each comprise a thickness of about 0.254 mm (10 mils).

24. The vertical FET according to claim 21, wherein a top area is connected by a metal clip.

25. The vertical FET according to claim 24, wherein the metal clip is manufactured from copper.

26. The vertical FET according to claim 24, wherein the metal clip provides for a section compensating for a semiconductor die thickness.

27. An integrated circuit device comprising at least one vertical FET according to claim 14, wherein the integrated circuit device provides for control functions for a switched mode power supply.

28. The integrated circuit device according to claim 27, comprising a microcontroller controlling said at least one vertical FET.
